(19) United States
(12) Patent Application Publication
(10) Pub. No.: US 2006/0102942 A1
(43) Pub. Date: May 18, 2006

(54) Ferroelectric memory and method for manufacturing the same

(76) Inventor: Akira Takahashi, Tokyo (JP)

Correspondence Address: RABIN & Berdo, PC, 1101 14TH STREET, NW, SUITE 500, WASHINGTON, DC, 20005, US

(21) Appl. No.: 11/266,256

(22) Filed: Nov. 4, 2005

(30) Foreign Application Priority Data
Nov. 18, 2004 (JP) 2004-334520

(51) Int. Cl. H01L 29/94

(52) U.S. Cl. 257/295

(57) ABSTRACT

The ferroelectric memory includes a ferroelectric capacitor structure having a ferroelectric layer and formed on a first insulating film, a first barrier film formed to cover the ferroelectric capacitor structure and the first insulating film, a second insulating film formed on the first barrier film, a first buried contact formed to pass through the second insulating film and the first barrier film, a first wiring layer formed on the second insulating film, an oxide film formed on the first wiring layer, a second barrier film formed to cover the oxide film, the first wiring layer and the second insulating film, a third insulating film formed on the second barrier film, a second buried contact formed to pass through the third insulating film, the second barrier film and the oxide film, and a second wiring layer formed on the third insulating film.

### BACKGROUND OF THE INVENTION

1. Field of the Invention

The present invention relates to a ferroelectric memory provided with a memory cell to store binary data as a polarization state of a ferroelectric layer and a method for manufacturing the same.

2. Description of Related Art

A Ferroelectric Random Access Memory (hereinafter referred to as a FeRAM) is known which represents a so-called ferroelectric memory.

A ferroelectric layer formed in the FeRAM is made of oxygen compound material.

In order to prevent diffusion of hydrogen generated during a passivation process into the ferroelectric layer, a hydrogen diffusion barrier film made of aluminum oxide is disposed on a metal wiring layer connected to the ferroelectric layer. A structure of such barrier film is disclosed, for example, in Japanese Patent Application Laid-Open No. 2002-43541.

Further, in order to reduce damage to the ferroelectric thin film (layer) due to the diffusion of hydrogen or moisture through the contact extending to a top electrode of the so-called ferroelectric memory, such manufacturing method of a semiconductor device is known that provides a conductive hydrogen barrier film after forming the contact (see Japanese Patent Application Laid-Open No. 2002-252336).

In addition, in order to suppress and prevent the deterioration of characteristics of a memory cell capacitor due to hydrogen or reducing atmosphere, a semiconductor memory device and a method for manufacturing the same are disclosed in Japanese Patent Application Laid-Open No. 2003-68987 in which a first and a second hydrogen barrier films are formed to respectively cover the top and the bottom sides of the memory cell capacitor.

As disclosed in the above-described Japanese Patent Application Laid-Open Nos. 2002-252336 and 2003-68987, the oxygen compound material constituting the ferroelectric layer may cause a reduction reaction due to, for example, the moisture (H₂O) or the hydrogen (H₂) generated therefrom which are unavoidably mixed in a CVD film formed around the ferroelectric layer. Because of such reduction reaction, polarization characteristics of the ferroelectric layer may deteriorate.

According to the structure disclosed in the above-described Japanese Patent Application Laid-Open No. 2002-43541, the hydrogen diffusion barrier film made of aluminum oxide (Al₂O₃) is formed directly on the metal wiring.

When a contact hole penetrating such hydrogen diffusion barrier film is formed, it is necessary to either, before the formation of the contact hole, form an opening in advance that communicates with the contact hole formed in the later process, or, after the formation of the contact hole, remove the hydrogen diffusion barrier film that is exposed from the contact hole.

When performing the etching of the hydrogen diffusion barrier film made of aluminum oxide, a mixed gas consisting of a mixture of chlorine (Cl₂) gas and boron trichloride (BCl₃) gas as etching gases, and argon (Ar) gas is generally employed.

According to the structure disclosed in Japanese Patent Application Laid-Open No. 2002-43541, the wiring layer disposed immediately below the hydrogen diffusion barrier film is made of material such as titanium (Ti) or titanium nitride (TiN). In general, the wiring layer is formed of an alloy such as AlSiCu or AlCu, titanium nitride (TiN), and so forth.

A mixed gas consisting of chlorine gas and boron trichloride gas used for etching the aluminum oxide layer is also used for etching the layer formed of an alloy such as AlSiCu or AlCu, titanium nitride (TiN), and so forth.

The etching rate of the aluminum oxide (the hydrogen diffusion barrier film) is now compared with that of the titanium nitride (the wiring layer) under the same conditions.

Typical etching conditions for etching the aluminum oxide using a mixed gas consisting of chlorine gas and boron trichloride gas are employed for the above comparison. Such etching conditions are, for example, chlorine gas flow rate of 50 sccm (cm³/min), boron trichloride gas flow rate of 50 sccm and electric power applied to an electrode of 100 Watts.

The etching rate of the aluminum oxide film is approximately 60 nm/min, whereas that of the titanium nitride film is approximately 480 nm/min. As can be understood from the above comparison, the latter etching rate is much faster than the former etching rate, that is, the etching selectivity is approximately 0.125.

Accordingly, during the formation process of the contact hole, i.e., the process of removing the hydrogen diffusion barrier film, etching of the wiring layer may immediately starts upon completion of the removal of the hydrogen diffusion barrier film. Consequently, there may be a problem in which the layer thickness of the wiring layer decreases or the contact hole penetrates the wiring layer.

If the thickness of the wiring layer decreases or the contact hole penetrates the wiring layer due to excessive etching, the contact area between a contact (a plug or a wiring) buried in the contact hole and the wiring layer becomes smaller. Consequently, electrical resistance is increased, thereby deteriorating electric characteristics of the ferroelectric memory.

### SUMMARY OF THE INVENTION

The present invention has been made in consideration of the above-described problems in the prior art. Specifically, an object of the present invention is to provide a ferroelectric memory having a structure to effectively prevent deterioration of a ferroelectric layer due to hydrogen, moisture, reducing atmospheres or the like.

Another object of the present invention is to provide a method of manufacturing the ferroelectric memory capable of preventing deterioration of electric characteristics of the ferroelectric memory due to a manufacturing process, in particular, a patterning process of a layer that is provided to prevent hydrogen, moisture, reducing atmospheres or the like from reaching the ferroelectric layer.

In order to accomplish the above objects, the ferroelectric memory of the present invention includes the following structures.

That is, the ferroelectric memory is provided with a plurality of memory cells. These memory cells include a ferroelectric capacitor structure. This ferroelectric capacitor structure is formed on a first insulating film and includes a ferroelectric layer.

The first barrier film to prevent penetration of hydrogen and moisture is formed so as to cover the ferroelectric capacitor structure and the first insulating film.

A second insulating film is formed on the first barrier film.

A first buried contact is connected to the ferroelectric capacitor structure by passing through the second insulating film and the first barrier film.

A first wiring layer is formed on the second insulating film so as to connect to the top surface of the first buried contact.

An oxide film is formed on the first wiring layer.

A second barrier film to prevent penetration of hydrogen and moisture is formed so as to cover the oxide film, the first wiring layer and the second insulating film.

A third insulating film is formed on the second barrier film.

A second buried contact is connected to the first wiring layer by passing through the third insulating film, the second barrier film and the oxide film.

A second wiring layer is formed on the third insulating film so as to connect to the top surface of the second buried contact.

Also, the manufacturing method of the ferroelectric memory according to the present invention mainly includes the following processes.

That is, a ferroelectric capacitor structure including a ferroelectric layer is formed on a first insulating film.

A first barrier film covering the ferroelectric capacitor structure and the first insulating film is formed to prevent penetration of hydrogen and moisture.

A second insulating film is formed on the first barrier film.

A first contact hole extending to the ferroelectric capacitor structure is formed through the second insulating film and the first barrier film.

A first buried contact is formed by filling the first contact hole.

A conductive layer is formed on the second insulating film so as to connect to the top surface of the first buried contact.

An oxide film layer is formed on the conductive layer.

A wiring structure having the first wiring layer and the oxide film so as to stack the oxide film on the first wiring layer is formed by patterning the conductive layer and the oxide film layer.

A second barrier film covering the wiring structure and the second insulating film is formed to prevent penetration of hydrogen and moisture.

A third insulating film is formed on the second barrier film.

A second precursor contact hole extending to the second barrier film is formed through the third insulating film.

The second barrier film exposed from the second precursor contact hole is removed.

A second contact hole passing through the second precursor contact hole and also exposing the surface of the first wiring layer is formed by removing the oxide film exposed from the second contact hole.

A second buried contact is formed by filling the second contact hole.

A second wiring layer is formed on the third insulating film so as to connect to the top surface of the second buried contact.

In accordance with the structure of the ferroelectric memory according to the present invention, hydrogen, moisture, reducing atmospheres or the like generated from inter-layer insulating films respectively formed on the top of the first and second barrier films are independently blocked by the first and the second barrier films. Accordingly, phenomena causing deterioration of the characteristics of the ferroelectric memory due to penetration of hydrogen, moisture, reducing atmospheres or the like to the ferroelectric layer can be effectively prevented.

In accordance with a manufacturing method of a ferroelectric memory of the present invention, the oxide film formed on the first wiring layer functions as an etching-stopper during the formation of the opening portion in the second barrier film, and therefore the first wiring layer is not etched in the etching process for the second barrier film. Consequently, the deterioration of the electric characteristics of the ferroelectric memory can be prevented. That is, the yield of the ferroelectric memory can be increased.

### BRIEF DESCRIPTION OF THE DRAWINGS

FIG. 1 is a cross-sectional view schematically showing major parts of a ferroelectric memory for illustrating a ferroelectric memory according to an embodiment of the present invention;

FIGS. 2A and 2B are cross-sectional views schematically showing major parts of the ferroelectric memory during a manufacturing process for illustrating a first manufacturing method of the ferroelectric memory according to an embodiment of the present invention;

FIGS. 3A and 3B are cross-sectional views for illustrating manufacturing processes subsequent to those of FIGS. 2A and 2B;

FIGS. 4A and 4B are cross-sectional views for illustrating manufacturing processes subsequent to those of FIGS. 3A and 3B;

FIGS. 5A and 5B are cross-sectional views schematically showing major parts of the ferroelectric memory for illustrating a second manufacturing method of the ferroelectric memory according to another embodiment of the present invention; and

FIGS. 6A and 6B are cross-sectional views for illustrating manufacturing processes subsequent to those of FIGS. 5A and 5B.

### DETAILED DESCRIPTION OF THE INVENTION

Embodiments of the present invention will be hereinafter described with reference to the accompanying drawings. It is to be understood that shapes, sizes, and positional relationship of the elements in the drawings are schematically shown to an extent for merely illustrating the present invention and the numerical conditions or the like described hereinafter are described for exemplary purposes only.

Structure of the Ferroelectric Memory

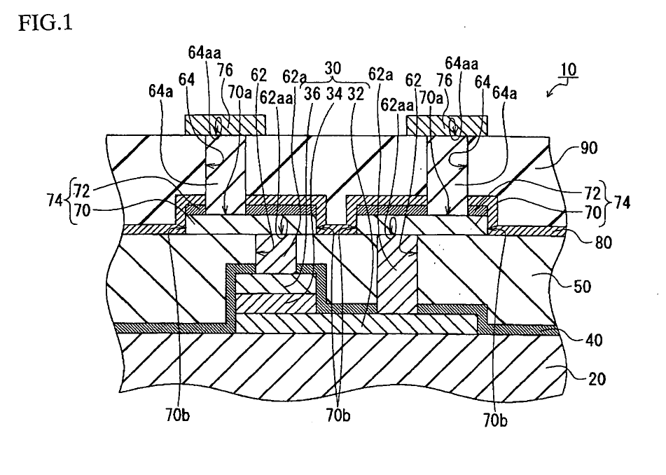

Referring to FIG. 1, an embodiment of a ferroelectric memory of the present invention will be described.

FIG. 1 is a cross-sectional view schematically showing major parts of a ferroelectric memory for illustrating the ferroelectric memory according to an embodiment of the present invention.

The ferroelectric memory of the present invention has features in structures of a first barrier film, a second barrier film and a wiring structure which are described below. Other elements of the memory may be configured by appropriately selecting suitable elements from conventional ferroelectric memories. Therefore, structure of these other elements and manufacturing processes thereof will be omitted from the following detailed description.

In general, the ferroelectric memory is formed in a semiconductor substrate. The semiconductor substrate is divided into a memory cell array region upon which a plurality of memory cells are formed in a matrix pattern and a peripheral circuit region encompassing the memory cell array region. In the peripheral circuit region, peripheral circuits such as a decoder circuit and a redundancy circuit are formed by a conventional wafer process.

In FIG. 1, only one memory cell is shown among a plurality of memory cells formed on the memory cell array region is described. It should be noted that, below the ferroelectric capacitor structure 30, there may exist the semiconductor substrate mentioned above, devices such as a plurality of transistors formed in the semiconductor substrate, and device isolation regions for isolating the devices from each other. However, these structures and a manufacturing method thereof are omitted from the detailed description, since these structures and the method are not major aspects of the present invention.

In the memory cell array region and the peripheral circuit region of the semiconductor substrate in which devices such as transistors are formed, a first insulating film 20 is formed. Preferably, the first insulating film 20 may be formed of, for example, silicon oxide film which is deposited by means of a chemical vapor deposition (CVD) method using ozone (O₃) and employing TEOS as material. The film may be hereinafter referred to as O₃-TEOS.

On the first insulating film 20 in the memory cell array region, the ferroelectric capacitor structure 30 is formed. The ferroelectric capacitor structure 30 has a conventional structure. Specifically, the ferroelectric capacitor structure 30 is formed by sequentially laminating a bottom electrode 32, a ferroelectric layer 34 and a top electrode 36. The bottom electrode 32 and the top electrode 36 may be preferably formed of, for example, platinum (Pt). The ferroelectric layer 34 may be preferably formed of, for example, SBT (SrBi₂Ta₂O₉) film.

A first barrier film 40 serves to prevent the penetration of hydrogen, moisture, reducing atmospheres, and so forth. Thickness of the film may be determined depending on the selected material such that penetration of hydrogen, moisture, reducing atmospheres, and so forth can be prevented.

The first barrier film 40 is formed to cover the ferroelectric capacitor structure 30 and the first insulating film 20. The first barrier film 40 is provided to protect the ferroelectric capacitor structure 30 against hydrogen, moisture, reducing atmospheres, and so forth. Accordingly, it is sufficient that the first barrier film 40 is formed to cover a region having the ferroelectric capacitor structure 30 of the ferroelectric memory 10.

The first barrier film 40 may be preferably formed of a thin film made of insulating metal oxide selected from a group consisting of aluminum oxide or alumina (Al₂O₃), titanium oxide (TiO₂) and tantalum oxide (Ta₂O₅).

On the first barrier film 40, a second insulating film 50 is formed. The second insulating film 50 is formed over an entire upper surface of the first insulating film 20 so as to cover the first barrier film 40.

Preferably, the second insulating film 50 may be formed of, for example, a silicon oxide film which is deposited by means of plasma CVD method employing TEOS as material. This film may be hereinafter referred to as P-TEOS film.

In the second insulating film 50, first contact holes 62 are formed. The first contact holes 62 are formed in such a way that they extend from a surface of the second insulating film 50 to the ferroelectric capacitor structure 30 by passing through the second insulating film 50 and the first barrier film 40. Another contact hole connecting with a device such as a transistor located below the first insulating film 20 may be also formed as the first contact hole 62 (not shown).

Preferably, the first contact holes 62 are filled with conductive material such as tungsten (W), thereby forming first buried contacts 62a. Accordingly, the first buried contacts 62a are connected to the ferroelectric capacitor structure 30 through the second insulating film 50 and the first barrier film 40.

On a surface of the second insulating film 50 where the first buried contact 62a is formed, a wiring structure 74 is formed. The wring structure 74 includes a first wiring layer 70 and an oxide film 72.

The first wiring layer 70 includes a plurality of wirings extending on the second insulating film 50. The first wiring layer 70 is connected to a top surface 62aa of the first buried contact 62a. The oxide film 72 is formed to cover a top surface 70a of the first wiring layer 70 and expose a side surface 70b.

Preferably, the first wiring layer 70 may be formed of a metal wiring made of material selected from a group consisting of, for example, AlSiCu, AlCu and titan nitride.

The oxide film 72 serves as an etching-stopper during an etching process for the second barrier film 80 which is described below. The oxide film 72 is therefore selected from material which is not etched by the etching process for the second barrier film 80. Thickness of the oxide film 72 may be determined so as not to be etched by the etching process for the second barrier film 80. Preferably, the oxide film 72 is made of, for example, silicon oxide (SiO₂).

The second barrier film 80 serves to prevent the penetration of hydrogen, moisture, reducing atmospheres, and so forth. Thickness of the second barrier film 80 is determined depending on the selected material such that the penetration of hydrogen, moisture, reducing atmospheres, and so forth can be prevented. The second barrier film 80 is formed so as to cover the oxide film 72, the first wiring layer 70 and the second insulating film 50. The second barrier film 80 is provided to protect the ferroelectric capacitor structure 30 against hydrogen, moisture, reducing atmospheres, and so forth. Accordingly, it is sufficient that the second barrier film 80 is formed to cover a region having the ferroelectric capacitor structure 30 of the ferroelectric memory 10.

Preferably, the second barrier film 80 may be formed of a thin film of insulating metal oxide selected from a group consisting of aluminum oxide or alumina (Al₂O₃), titanium oxide (TiO₂) and tantalum oxide (Ta₂O₅).

A third insulating film 90 is formed on the second barrier film 80. Preferably, the third insulating film 90 is made of, for example, P-TEOS film.

Second contact holes 64 expose the surfaces 70a of the first wiring layer 70 from a surface of the third insulating film 90 by passing through the second barrier film 80 and the oxide film 72.

Preferably, the second contact holes 64 are filled with conductive material such as tungsten (W), thereby forming a second buried contacts 64a.

Accordingly, the second buried contacts 64a are connected to the first wiring layer 70 through the third insulating film 90, the second barrier film 80 and the oxide film 72.

A second wiring layer 76 is formed on the third insulating film 90 so as to be connected to a top surface of the second buried contacts 64a.

The second wiring layer 76 includes a plurality of wirings extending on the third insulating film 90. The second wiring layer 76 is connected to a top surface 64aa of the second buried contact.

Preferably, the second wiring layer 76 may be formed of a metal wiring made of, for example, material such as AlSiCu, AlCu, or titanium nitride.

An additional wiring layer, for example, may be formed on the second wiring layer 76 to acheive a multi-layer wiring structure (not shown).

Method for Manufacturing the Ferroelectric Memory

First Manufacturing Method

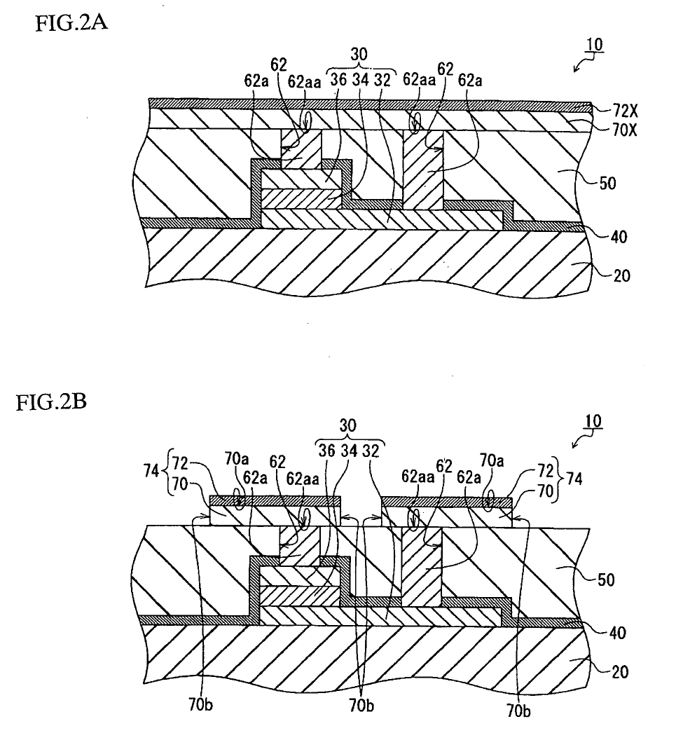

A first manufacturing method of the above-described ferroelectric memory 10 according to an embodiment of the present invention will be described with reference to FIGS. 2A, 2B, 3A, 3B, 4A and 4B.

As described above, the ferroelectric memory of the present invention has characteristics in structures of the first and second barrier films and the wiring structure. In manufacturing elements other than these structures mentioned above, manufacturing processes similar to those for elements of the conventional ferroelectric memory can be applied. Accordingly, detailed descriptions thereof are omitted.

FIG. 2A is a cross-sectional view schematically showing major parts of the ferroelectric memory during a manufacturing process for illustrating the first manufacturing method of the ferroelectric memory according to an embodiment of the present invention. FIG. 2B is a diagram illustrating a manufacturing process subsequent to that of FIG. 2A.

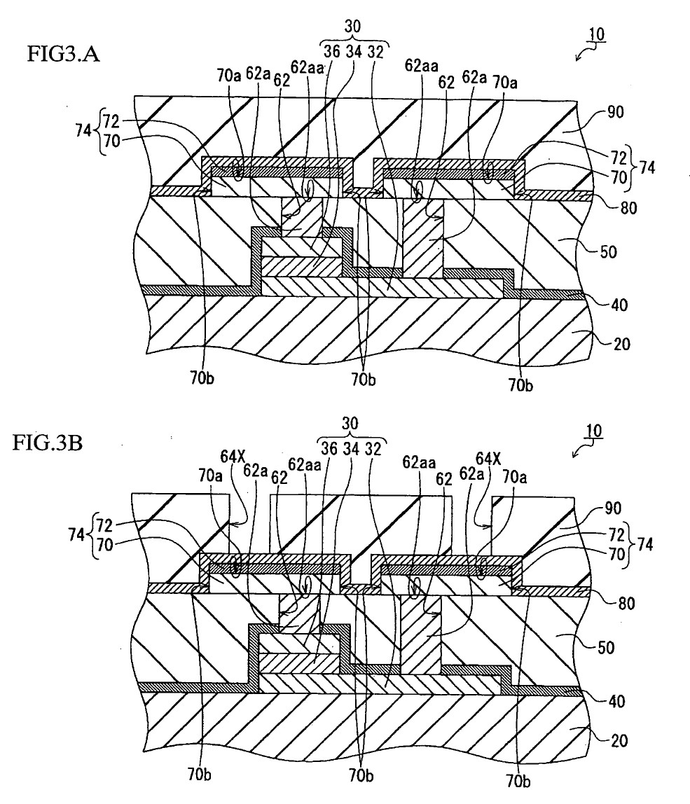

FIGS. 3A and 3B are diagrams illustrating manufacturing processes subsequent to those of FIGS. 2A and 2B.

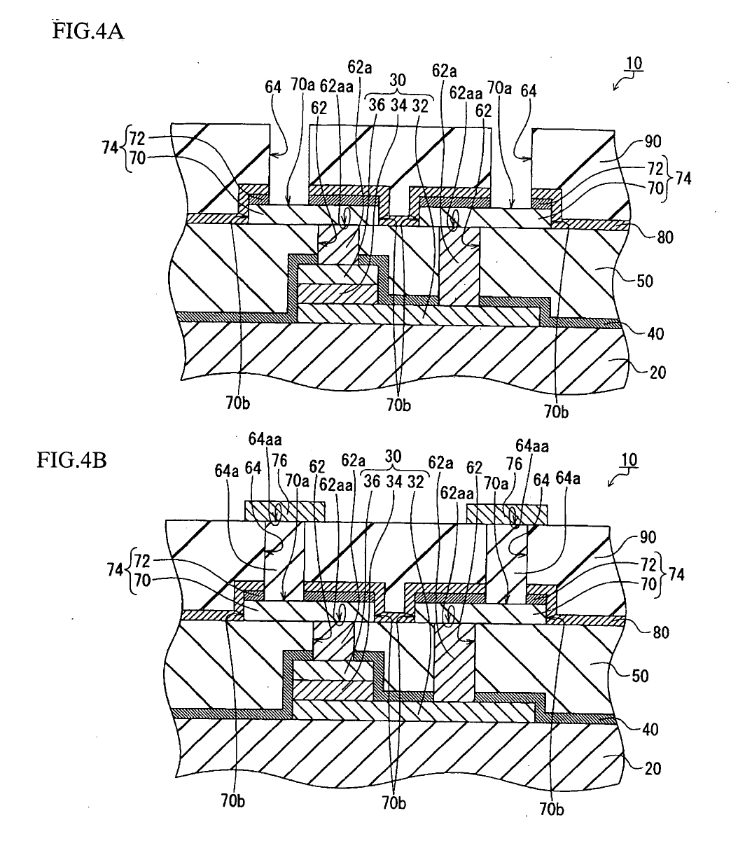

FIGS. 4A and 4B are diagrams illustrating manufacturing processes subsequent to those of FIGS. 3A and 3B.

Firstly, a semiconductor substrate such as a silicon substrate is prepared. In the semiconductor substrate, a plurality of ferroelectric memories is formed in a matrix pattern.

On the semiconductor, a field oxide film is formed and then a device such as a transistor (not shown) is formed by a conventional wafer process, e.g., LOCOS method.

Thereafter, over an entire surface of the semiconductor substrate, a first insulating film 20 is formed. Specifically, for example, an O₃-TEOS film may be formed by means of a conventional plasma CVD method using ozone (O₃) and employing TEOS as material.

Thereafter, as shown in FIG. 2A, the ferroelectric capacitor structure 30 including the ferroelectric layer 34 is formed on the first insulating film 20 in accordance with a conventional method.

Specifically, the bottom electrode 32, the ferroelectric layer 34 and the top electrode 36 are laminated by using the above-described material, and then patterning is performed in accordance with a conventional method.

Thereafter, the first barrier film 40 is formed so as to cover the ferroelectric capacitor structure 30 and the first insulating film 20. The first barrier film 40 may be formed of a thin film of aluminum oxide by using a conventional method, e.g., sputtering.

On the first barrier film 40, the second insulating film 50 is formed. The second insulating film 50 may be formed of P-TEOS film by using a conventional method, e.g., a plasma CVD.

Thereafter, the first contact holes 62 are formed that extend to the ferroelectric capacitor structure 30 through the second insulating film 50 and the first barrier film 40. In this embodiment, two contact holes are formed which respectively extend to the bottom electrode 32 and the top electrode 36. In addition, another contact hole is formed as the first contact hole 62 (not shown) which is connected to a device such as a transistor disposed below the first insulating film 20.

The first contact holes 62 may be formed by a conventional method such as a photolithography process using photoresist and a dry etching process.

Thereafter, the first contact holes 62 are filled so as to form the first buried contacts 62a. The first buried contacts 62a may be formed by filling the holes with conductive material such as tungsten (W) in accordance with a conventional method.

Thereafter, on the second insulating film 50, a conductive layer 70X is formed to connect with the top surface 62aa of the first buried contact 62a.

The conductive layer 70X may be formed of a thin film by a conventional method such as a sputtering process, and the layer is made of material selected from a group consisting of AlSiCu, AlCu and titanium nitride.

Furthermore, on the conductive layer 70X, an oxide film layer 72X is formed. The oxide film layer 72X may be preferably formed of a thin film of, e.g., silicon oxide in accordance with a conventional method.

Subsequently, as shown in FIG. 2B, the conductive layer 70X and the oxide film layer 72X are sequentially patterned in accordance with a conventional method so that a wiring structure 74 having a wiring pattern extending over the second insulating film 50 is formed. The wiring structure 74 has such a structure that the oxide film 72 is laminated on the surface 70a of the first wiring layer 70 and the side surface 70b of the first wiring layer 70 is exposed.

Furthermore, as shown in FIG. 3A, a second barrier film 80 is formed to cover the wiring structure 74 and the second insulating film 50. The second barrier film 80 may be made of the same material as the first barrier film 40 and formed by the same process as the first barrier film 40.

Thereafter, on the second barrier film 80, a third insulating film 90 is formed. The third insulating film 90 may be formed in a similar manner as the above-described second insulating film 50.

Thereafter, as shown in FIG. 3B, second precursor contact holes 64X extending to the second barrier film 80 through the third insulating film 90 are formed. This second precursor contact hole 64X is formed by exposing the surface of the second barrier film 80. The second precursor contact holes 64X may be formed in a similar manner as the first contact holes 62.

Subsequently, as shown in FIG. 4A, the second barrier film 80 and the oxide film 72 exposed from the second precursor contact holes 64X are sequentially removed.

The removal of the second barrier film 80 is performed by a dry etching process employing the oxide film 72 as an etching-stopper.

When, for example, the second barrier film 80 is an aluminum oxide layer, the second barrier film 80 is etched using the oxide film 72 made of a silicon oxide film as an etching-stopper.

Specifically, etching may be preferably performed using a mixed discharge gas of boron trichloride gas and chlorine gas under the conditions of boron trichloride gas flow rate of 70 sccm and chloride gas flow rate of 30 sccm, the discharge pressure of 2 Pa (Pascal), the electrode power of 70 Watts, and the electrode temperature of 20 degree C. Assuming that the first wiring layer 70 is formed of, for example, titanium nitride, the etching rate of the silicon oxide film under the above-described conditions corresponds to approximate ⅓ to ¼ of the etching rate of the titanium nitride. Accordingly, even though the etching of the oxide alumina layer, i.e., the second barrier film 80 is performed under the above-described conditions, the first wiring layer 70 is not etched by this etching process, and thus thickness thereof does not decrease, and also the contact hole does not penetrate the wiring layer. This is because the oxide film 72 functions as the etching-stopper.

Thereafter, the oxide film 72 exposed from the second precursor contact holes 64X is removed. The removal of the oxide film 72 may be performed in accordance with a conventional method such as so-called oxide film etching.

The removing process of the oxide film 72 forms second contact holes 64 which connect to the second precursor contact holes 64X and expose the surfaces 70a of the first wiring layer 70.

Further, as shown in FIG. 4B, second buried contacts 64a filling the second contact holes 64 are formed. The second buried contacts 64a may be formed in a similar manner as the forming process for the above-described first buried contact 62a.

Thereafter, a second wiring layer 76 is formed which extends over the third insulating film 90 and connects to top surfaces 64aa of the second buried contacts 64a. The second wiring layer 76 may be formed in a similar manner as the formation process for the above-described first wiring layer 70.

Finally, upon completion of the wafer process, the semiconductor wafer is divided into a plurality of ferroelectric memory chips through dicing using a conventional dicing apparatus, thereby obtaining a plurality of ferroelectric memory chips.

Second Manufacturing Method

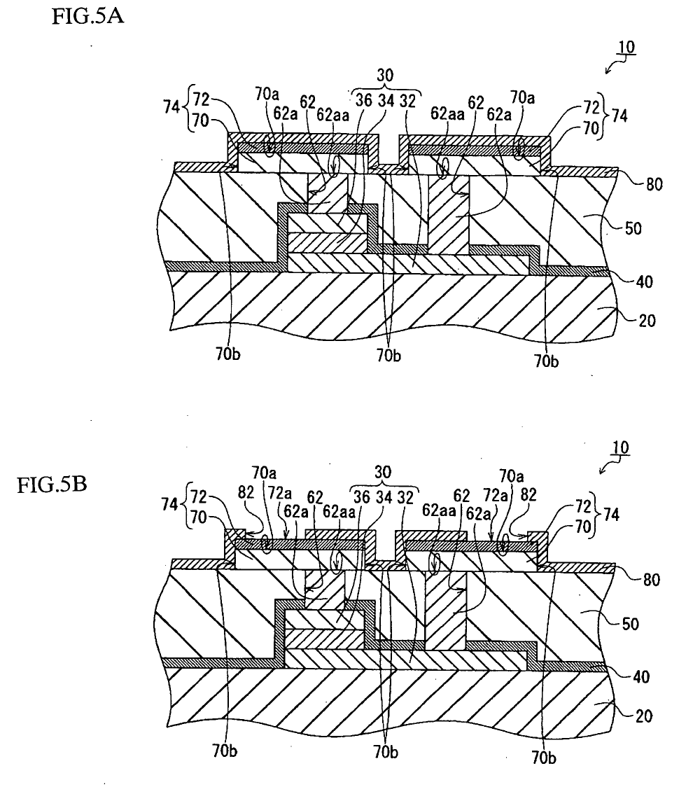

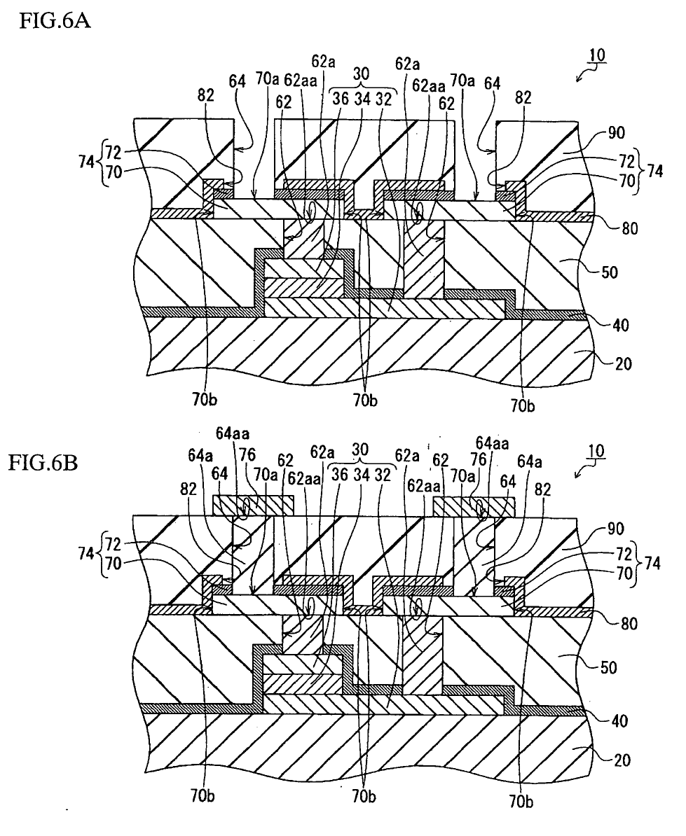

A second manufacturing method of the above-described ferroelectric memory 10 according to another embodiment of the present invention will be described with reference to FIGS. 5A, 5B, 6A and 6B.

This embodiment employs a second manufacturing method in which an opening portion is preformed in a second barrier film. Noted that manufacturing processes similar to those of the first manufacturing method are omitted from the following detailed description.

As shown in FIG. 5A, a similar manufacturing method as the first manufacturing method is employed until the formation of the second barrier film 80.

Subsequently, as shown in FIG. 5B, an opening portion 82 is formed through the second barrier film 80 so as to expose a portion of a surface 72a of the oxide film 72. The opening portion 82 is formed so that a diameter thereof can communicate with a second contact hole formed in the subsequent process, and a position thereof is aligned with that of the second contact hole. The opening portion 82 is formed in a similar manner as the above-described first manufacturing method. Specifically, a dry etching process is employed using the oxide film 72 as an etching-stopper.

When, for example, the second barrier film 80 is the aluminum oxide film, the second barrier film 80 is etched using the oxide film 72 made of silicon oxide as an etching-stopper.

Specifically, the opening portion 82 passing through the second barrier film 80 may be formed by patterning a resist using a conventional photolithography process so as to obtain a resist mask which opens the second barrier film 80 in accordance with the position of the opening portion 82, and then performing dry etching.

Preferably, the dry etching may be performed using a mixed discharge gas of boron trichloride (BCl₃) gas and chloride gas under the conditions of boron trichloride (BCl₃) gas flow rate of 70 sccm and the chlorine gas flow rate of 30 sccm, the discharge pressure of 2 Pa (Pascal), the electrode power of 70 W (Watts), and the electrode temperature of 20 degree C.

Similar to the first manufacturing method, assuming that the first wiring layer 70 is made of, for example, titanium nitride, the etching rate of the silicon oxide film under the above-described conditions corresponding to approximately ⅓ to ¼ of the etching rate of the titanium nitride. As a result, even though the etching of the aluminum oxide layer, i.e., the second barrier film 80 is performed under the above-described conditions, the first wiring layer 70 is not etched by this etching process, and thus a layer thickness of the first wiring layer 70 does not decrease, and also the opening portion 82 does not penetrate the wiring layer. This is because the second oxide film 72 functions as an etching-stopper.

Thereafter, as shown in FIG. 6A, a third insulating film 90 filling the opening portion 82 is formed on the second barrier film 80 in a similar manner as the first manufacturing method.

Subsequently, the second contact hole 64 is formed to expose the surface 70a of the first wiring layer 70 through the third insulating film 90 and the oxide film 72 such that either it can communicate with the previously formed opening portion 82, that is, a diameter of the second contact hole is smaller than that of the opening portion 82, or it has the same diameter as that of the opening portion 82. The process may be performed in a similar manner as the formation process of the second precursor contact hole 64X of the first manufacturing method. The oxide film 72 is also removed by the photolithography process and the etching process to form the second contact hole 64. Therefore, according to the second manufacturing method, the formation process of the second contact hole to expose the surface 70a of the first wiring layer 70 from the surface of the third insulating film 90 can be performed through a single etching step.

Consequently, the number of manufacturing processes of the ferroelectric memory can be reduced, and therefore manufacturing costs can be reduced.

As shown in FIG. 6B, similar to the first manufacturing method, the second buried contact 64a filling the second contact hole 64 is formed, and the second wiring layer 76 is formed so as to extend over the third insulating film 90 and connect to the top surface of the second buried contact 64a.

This application is based on a Japanese patent application No. 2004-334520 which is herein incorporated by reference.

What is claimed is:

1. A ferroelectric memory with a plurality of memory cells comprising:
a ferroelectric capacitor structure included in each of the memory cells, the structure being formed on a first insulating film and including a ferroelectric layer;
a first barrier film formed to cover the ferroelectric capacitor structure and the first insulating film so as to prevent penetration of hydrogen and moisture;
a second insulating film formed on the first barrier film;
a first buried contact connected to the ferroelectric capacitor structure by passing through the second insulating film and the first barrier film;
a first wiring layer formed on the second insulating film so as to connect with a top surface of the first buried contact;
an oxide film formed on the first wiring layer;
a second barrier film formed to cover the oxide film, the first wiring layer and the second insulating film so as to prevent penetration of hydrogen and moisture;
a third insulating film formed on the second barrier film;
a second buried contact connected to the first wiring layer by passing through the third insulating film, the second barrier film and the oxide film; and
a second wiring layer formed on the third insulating film so as to connect with a top surface of the second buried contact.

2. The ferroelectric memory according to claim 1, wherein the first barrier film and the second barrier film are independent from each other, and formed of insulating metal oxide selected from a group consisting of aluminum oxide, titanium oxide and tantalum oxide.

3. The ferroelectric memory according to claim 1, wherein the oxide film is a silicon oxide film.

4. A method for manufacturing a ferroelectric memory, the method comprising the steps of:
forming, on a first insulating film, a ferroelectric capacitor structure including a ferroelectric layer;
forming a first barrier film covering the ferroelectric capacitor structure and the first insulating film so as to prevent penetration of hydrogen and moisture;
forming a second insulating film on the first barrier film;
forming a first contact hole extending to the ferroelectric capacitor structure by passing through the second insulating film and the first barrier film;
forming a first buried contact by filling the first contact hole;
forming a conductive layer on the second insulating film to connect with a top surface of the first buried contact;
forming an oxide film layer on the conductive layer;
forming a wiring structure having a first wiring layer and an oxide film so as to stack the oxide film on the first wiring layer by patterning the conductive layer and the oxide film layer;
forming a second barrier film covering the wiring structure layer and the second insulating film so as to prevent penetration of hydrogen and moisture;
forming a third insulating film on the second barrier film;
forming a second precursor contact hole extending to the second barrier film through the third insulating film;
removing the second barrier film exposed from the second precursor contact hole;
forming a second contact hole communicating with the second precursor contact hole and exposing a surface of the first wiring layer by removing the oxide film exposed from the second precursor contact hole;
forming a second buried contact by filling the second contact hole; and
forming a second wiring layer on the third insulating film to connect with a top surface of the second buried contact.

5. A method for manufacturing a ferroelectric memory, the method comprising the steps of:
forming, on a first insulating film, a ferroelectric capacitor structure including a ferroelectric layer;
forming a first barrier film covering the ferroelectric capacitor structure and the first insulating film so as to prevent penetration of hydrogen and moisture;
forming a second insulating film on the first barrier film;
forming a first contact hole extending to the ferroelectric capacitor structure by passing through the second insulating film and the first barrier film;
forming a first buried contact by filling the first contact hole;
forming a conductive layer on the second insulating film to connect with a top surface of the first buried contact;
forming an oxide film layer on the conductive layer;
forming a wiring structure having a first wiring layer and an oxide film so as to stack the oxide film on the first wiring layer by patterning the conductive layer and the oxide film layer;
forming a second barrier film covering the wiring structure and the second insulating film so as to prevent penetration of hydrogen and moisture;
forming an opening portions in the second barrier film so as to expose the oxide film;
forming a third insulating film on the second barrier film so as to bury the opening portion;
forming a second contact hole so as to communicate with the opening portion, pass through the third insulating film and the oxide film, and expose a surface of the first wiring layer;
forming a second buried contact for filling the second contact hole; and
forming a second wiring layer on the third insulating film to connect with a top surface of the second buried contact.
